(19) United States
(12) Patent Application Publication
(10) Pub. No.: US 2007/0241825 A1
(43) Pub. Date: Oct. 18, 2007

(54) Phase Locked Loop Circuit

(76) Inventor: Winfrid Birth, Veitbsronn (DE)

Correspondence Address: PHILIPS ELECTRONICS NORTH AMERICA CORPORATION;INTELLECTUAL PROPERTY & STANDARDS, 370 W. TRIMBLE ROAD MS 91/MG, SAN JOSE, CA, 95131, US

(21) Appl. No.: 11/578,499

(22) PCT Filed: Apr. 11, 2005
(86) PCT No.: PCT/IB05/51171

§ 371 Date: Oct. 12, 2006

(30) Foreign Application Priority Data
Apr. 15, 2004 (EP) 04101532.2

(51) Int. Cl. H03L 7/089

(52) U.S. Cl. 331/25

(57) ABSTRACT

Phase locked loop circuit (PLL-circuit) comprising a phase comparator (30) for detecting a phase difference ΔΦ between an input reference signal U_{ref} and an input signal U_{p,in}, wherein Kₚ is a phase detector gain of said phase comparator, a voltage controlled oscillator (VCO) for generating a periodic output signal U_{vco,out} having an angular frequency ω_{vco,out} depending on an input signal U_{VCO,in}, wherein K_{vco} is a voltage controlled oscillator gain of said voltage controlled oscillator, and a controller adapted to control the phase detector gain Kₚ during an operation of the phase locked loop circuit in such a way that a loop gain K:=Kₚ*K_{vco} remains within a predetermined range during the operation of the phase locked loop circuit.

The present invention relates to a phase locked loop circuit. The purpose the phase locked loop circuit (PLL) is to synchronize an output signal with a reference signal.

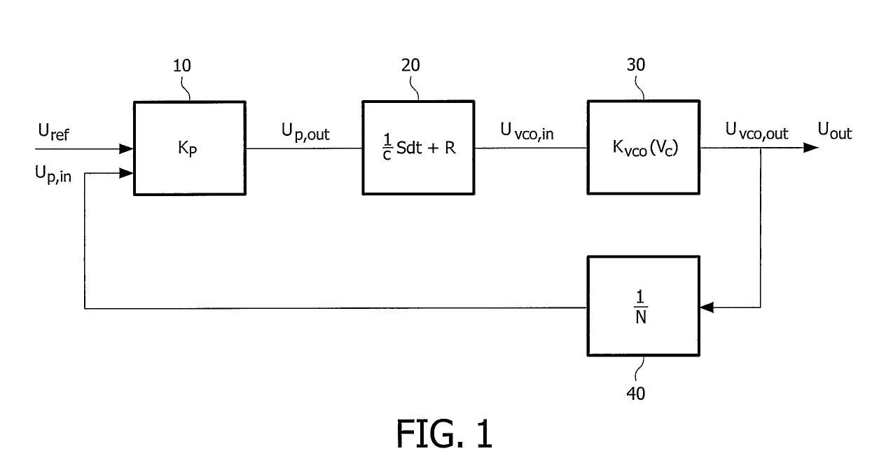

FIG. 1 shows a conventional phase locked loop circuit. U_{ref} designates the reference signal and the output signal is called Uₒᵤₜ in FIG. 1. The purpose of the PLL-circuit in FIG. 1 is to provide an output signal Uₒᵤₜ having a fixed frequency with regard to the reference signal U_{ref}. The desired frequency relationship between the frequency f_{ref} of the reference signal U_{ref} and the frequency fₒᵤₜ of the output signal is the following:
fₒᵤₜ=N*f_{ref} (1)
N stands for the real number, which represents the frequency relationship between the output signal Uₒᵤₜ and the reference signal U_{ref}.

The PLL-circuit comprises a phase comparator 10 shown in FIG. 1. The phase comparator receives the reference signal U_{ref} and a further input U_{p,in}. The phase comparator 10 further comprises a single output U_{p,out}. The output of the phase comparator depends on the phase difference ΔΦ between the input signals U_{ref} and U_{p,in}.
U_{p,out}=U_{p,out} (ΔΦ) (2)

The output U_{p,put} of the phase comparator 10 at an operating point ΔΦ₀ is equal to zero. The relationship between the output U_{p,out} of the phase comparator 10 and the phase difference ΔΦ in the vicinity of the operating point ΔΦ₀ may be approximated by the following equation:
U_{p,out}˜Kₚ*(ΔΦ-ΔΦ₀) (3)

As can be seen from equation 3, U_{p,out} is equal to zero for ΔΦ=ΔΦ₀. Equation 3 represents the ideal behavior of the phase comparator. Once the phase difference ΔΦ reaches ΔΦ₀, the output of the phase comparator is equal to zero and consequently the PLL-circuit stops adjusting the frequency of the output signal Uₒᵤₜ. Since the phase difference between two signals is a constant only, if both signals have the same frequency, the condition ΔΦ=ΔΦ₀ means, that the input signal U_{p,in} and the reference signal U_{ref} have the same frequency. The phase-frequency relationship is determined by the following equation:

$$\frac{ⅆ ( ΔΦ )}{ⅆ t} = {w}_{ref} - {w}_{p , in} \qquad ( 4 )$$

w_{ref} is the angular frequency of the reference signal and w_{p,in} is the angular frequency of the input signal U_{p,in} of the phase comparator. Hence, the phase comparator has an integrating behavior:

$$ΔΦ = {\int }_{0}^{t} Δ w ⅆ {t}^{′} \qquad ( 5 )$$

Δw represents the difference between the angular reference frequency w_{ref} and the angular input frequency w_{p,in}. According to equation 3 the output U_{p,out} of the phase comparator 10 is approximately proportional to the detected phase difference ΔΦ at the input of the phase comparator. The amplitude of the output signal U_{p,out} is a measure of the phase difference at the input. The output of the phase comparator U_{p,out} is fed to a loop filter 20 shown in FIG. 1. The loop filter 20 is conventionally a low pass filter. The loop filter suppresses high frequency components of the output signal U_{p,out} of the phase comparator. The frequency components of the output U_{p,out} of the phase comparator do not correspond to the frequency of the reference signal U_{ref} or the output signal Uₒᵤₜ. The suppressed frequencies are the frequencies of change of the detected phase difference.

The output of the loop filter is fed to a voltage-controlled oscillator VCO (30). The voltage-controlled oscillator 30 generates a periodic output signal U_{vco,out} having a frequency, which depends, on the amplitude of the input signal U_{vco,in} of the voltage controlled oscillator.
f_{vco}=f_{vco} (U_{vco,in}) (6)
f_{vco} is the frequency of the output signal U_{vco,out} of the voltage-controlled oscillator. The output signal of the voltage controlled oscillator correspond to the following equation in the vicinity of the working point U_{vco,in}=0 of the VCO.
ω_{vco}˜ω_{vco,0}+K_{vco}*U_{vco,in} (7)
ω_{vco} depicts the angular frequency of the VCO. ω_{vco,0} is the angular frequency of the output signal of the VCO, when the input signal U_{vco,in} is zero. K_{vco} is the gain factor of the VCO. The previous equation depicts the behavior of an ideal voltage controlled oscillator. The output angular frequency of the VCO corresponds approximately to the equation (7) in the vicinity of the operating point U_{vco,in}=0 of a real voltage controlled oscillator. Therefore, the gain factor K_{vco} is defined by the following equation:

$${K}_{vco} = \frac{\partial {ω}_{vco}}{\partial {U}_{vco , in}} ( {U}_{vco , in} ) \qquad ( 8 )$$

Correspondingly, the gain Kₚ of the phase comparator is defined by:

$${K}_{p} = \frac{\partial {U}_{p , out}}{\partial ΔΦ} ( ΔΦ ) \qquad ( 9 )$$

Furthermore, the phase locked loop shown in FIG. 1 comprises a frequency divider 40. The output signal of the voltage controlled oscillator VCO (30) is fed to the input of the frequency divider 40. The frequency divider 40 divides the frequency of the output signal Uₒᵤₜ by the real number N. N is the factor depicted in equation (1). The output signal of the frequency divider is fed to the phase comparator and corresponds to the input U_{p,in} of the phase comparator. The angular frequency ω_{p,in} of the input signal to the phase comparator 10 is equal to the output signal of the voltage controlled oscillator 30 divided by N, see equation (10)
ω_{p,in}=ω_{vco}/N (10)

An analysis of the loop behavior of the phase locked loop PLL shown in FIG. 1 leads to the following equation:

$$ΔΦ \cdot \frac{{K}_{p} \cdot {K}_{vco}}{N \cdot s} F ( s ) = {Φ}_{p , in} \qquad ( 11 )$$

Φ_{p,in} is the phase of the input signal U_{p,in} of the phase comparator. ΔΦ=Φ_{ref}−Φ_{p,in} is the phase difference at the input of the phase comparator, wherein Φ_{ref} is the phase of the reference signal U_{ref}. F(s) is the transfer function of the loop filter 20 shown in FIG. 1 and s is equal to i*w, where i²=−1 and w is the angular phase frequency. When the phase of the input signal Φ_{p,in} approaches the reference phase Φ_{ref}, the phase locked loop converges. The phase difference ΔΦ at the input of the phase comparator 10 approaches zero. Therefore, the phase difference practically does not change in time, so that

$$\frac{ⅆ ΔΦ}{ⅆ t}$$

is equal to zero. This means, that the ω_{ref} is equal to ω_{p,in} (see equation (4)). The output frequency of the voltage controlled oscillator ω_{vco} is approximately equal to N times w_{ref} (see equation (10)). The frequency of the output signal is equal to N times the frequency of the reference signal as suggested in equation (1).

The transfer function H(s) of the phase locked loop is given by:

$$H ( s ) = \frac{{Φ}_{p , in} ( s )}{{Φ}_{ref} ( s )} = \frac{F ( s ) \cdot {K}_{p} \cdot {K}_{vco} \text{/} N}{s + F ( s ) {K}_{p} \cdot {K}_{vco} / N} \qquad ( 12 )$$

The error function of the phase locked loop Hₑ(s) is given by the following equation:

$${H}_{e} ( s ) = \frac{ΔΦ ( s )}{{Φ}_{ref}} = 1 - H ( s ) = \frac{s}{s + {K}_{vco} \cdot {K}_{p} \cdot F ( s ) \text{/} N} \qquad ( 13 )$$

The product K_{vco}*Kₚ is commonly called the loop gain of the PLL-circuit. The bandwidth of the PLL-circuit is strongly influenced by the loop gain K=Kₚ*K_{vco}. The frequency bandwidth of the PLL-circuit is a characteristic of the transfer function H(s). The frequency bandwidth denotes the width of the frequency range, in which the transfer function H(s) hardly suppresses frequency components of the transferred signal. The transfer function H(s) of the PLL-circuit depends on the transfer function F(s) of the loop filter. The loop filter itself usually is a low pass filter. Consequently the transfer function of the PLL-circuit is a low pass filter. A precise definition of the bandwidth may correspond to the frequency range of the transfer function H(s), in which the attenuation of the transfer function H=20*log(l/H(s)) is equal to or greater than 3 decibel. The greater the factor K=Kₚ*K_{vco} is, the greater bandwidth of the transfer function is. The so-called zero-decibel-bandwidth of the PLL-circuit corresponds to the frequency range, in which the transfer function H(s) is equal to or greater than 1. This is also called the unity-gain-bandwidth fA.

The bandwidth fA is supposed to be as large as possible, so that the phase locked loop may react fast to changing inputs, but the low pass filter characteristic of the transfer function is also desired in order to suppress noise. A suitable compromise between the PLL-control-speed and the desired low pass frequency characteristics has to be chosen. Therefore, the factor K=Kₚ*K_{vco} has to lie in a predetermined range, in order to fulfill the required filter characteristics.

Nevertheless, conventional phase locked loops exhibit considerable noise and are slow to react to changing inputs in particular, if the phase locked loop is not operating in lock.

It is object of the present invention to provide a phase locked loop circuit (PLL-circuit), which overcomes the above-mentioned problems of the state of the art.

The previous discussion of the filter characteristics of the transfer function H(s) of the phase locked loop-circuit is based on the assumption, that the voltage controlled oscillator generates an output signal, the frequency of which is a linear function of the input to the voltage controlled oscillator. This is an idealization. In reality the gain factor K_{vco} of the voltage controlled oscillator 30 depends on the input voltage to the voltage-controlled oscillator. Hence, the loop gain K=Kₚ*K_{vco} changes dynamically during the operation of the phase locked loop. The size of the loop gain K may exceed the predetermined range. Consequently, noise components may not be suppressed sufficiently anymore. The loop gain factor K may decrease during PLL-operation. Consequently, the adaptation speed of the PLL-circuit may be reduced significantly.

A phase locked loop circuit according to the appended claim 1 solves the problem. The phase locked loop circuit comprises a phase comparator for detecting a phase difference ΔΦ between an input reference signal U_{ref} and an input signal U_{p,in}. An output U_{p,out} of the phase comparator is equal to Kₚ*(ΔΦ-ΔΦ₀) in the vicinity of the operating point ΔΦ₀ of the phase detector. The phase locked loop circuit comprises further a voltage-controlled oscillator having an input signal U_{vco,in} and a periodic output signal U_{vco,out}. An angular frequency ω_{vco,out} of the output signal U_{vco,out} is equal to ω₀+K_{vc0}*U_{vc0,in} in the vicinity of an operating point U_{vco,in}=0 of the VCO. ω₀ is an angular frequency of the output signal U_{vco}, when the input signal U_{vco,in} is equal to zero. A controller adapted to control the phase detector gain Kₚ is further provided with the phase locked loop circuit. During an operation of the phase locked loop circuit the controller adapts Kₚ in such a way that K=Kₚ*K_{vco} remains within a predetermined range during operation. If the voltage controlled oscillator gain K_{vco} increases significantly, then the phase comparator gain Kₚ is decreased, such that K remains within the predetermined range. Conversely, if the voltage controlled oscillator gain K_{vco} decreases, the phase detector gain Kₚ is eventually increased in order to guarantee that K remains within the predetermined range. Since the voltage-controlled oscillator gain K_{vco} depends on the input signal to the voltage-controlled oscillator U_{vco,in}, the loop gain K must be maintained within the predetermined range by controlling Kₚ. The characteristics of the transfer function of the phase locked loop are maintained in such a way, that high frequency noise is suppressed by the low pass filter characteristics and the adaptations speed is maintained within a reasonable range.

Preferably, the controller is adapted to control the phase detector gain Kₚ in such a way, that the phase detector gain is proportional to 1/K_{vco}. In this case, the loop gain K would remain constant. If the phase comparator gain Kₚ is controlled using the input signal U_{vco,in} to the voltage controlled oscillator, then the phase comparator gain is a continuous function of the input signal U_{vco,in} to the voltage-controlled oscillator.

The drawbacks of this solution are, that the phase comparator having a phase comparator gain Kₚ continuously depending on the input voltage U_{vco,in}, would have to also guarantee the high spectral purity of the phase locked loop circuit, that may be achieved with constant values of the comparator gain Kₚ. The phase comparator gain of a particular phase comparator called phase frequency detector (PFD) is determined by a current Iₚ. The noise requirements for this current are very strict in particular in wireless communication systems. The noise is restricted in this case to the noise of the elementary current sources. If a complex analogue circuit is used for controlling the current Iₚ of the phase frequency detector, then the noise is increased in the phase locked loop.

Therefore, it is preferable to provide a controller with a phase locked loop circuit, which is adapted to control the phase comparator gain Kₚ in such a way, that Kₚ is proportional to a step function approximating 1/K_{vco}. The preferable noise characteristics of phase comparators using a constant phase comparator gain Kₚ are maintained, if a step function is used, since Kₚ is constant for most of the time of operation. Kₚ is switched to another value in order to approximate 1/K_{vco}. Preferable, the phase comparator gain Kₚ is controlled depending on the input signal U_{vco,in} of the voltage controlled oscillator. The input to the voltage-controlled oscillator is fed to the controller, which in turn controls the phase comparator gain. The approximation of the function 1/K_{vco} by a step function corresponds to the digitalization of an analogue signal. A constant value is attributed to the phase detector gain Kₚ, as long as the difference between the constant value and the continuously changing function 1/K_{vco} does not exceed a predetermined range. In this way the difference between the step function and the continuous function 1/K_{vco} remains small. Said difference constitutes the range, in which the loop gain K=Kₚ*K_{vco} changes during operation of the phase locked loop circuit.

Preferably the controller of the phase locked loop circuit is adapted to stop controlling the phase comparator gain Kₚ, when a predetermined period of time T1 has elapsed. If the value of the phase comparator gain Kₚ is changed after the time T1 has elapsed, i.e. also during operation of the phase locked loop, tuning in processes of the phase locked loop may be disturbed. Minute details may be disturbing, since every control loop such as a phase locked loop has small static errors that are unavoidable. Several steady-state phase errors may occur. These errors are influenced by the value of the phase comparator gain Kₚ. Whenever the phase comparator gain Kₚ is changed, a dynamic phase error is generated at the voltage-controlled oscillator that is N-times as great as the phase error at the comparator. Therefore, the drawbacks to the adaptation process are avoided by stopping the adaptation of Uₚ after the predetermined time Ti has elapsed. The phase comparator gain Kₚ is adapted fast in few steps.

A preferred embodiment of the present invention is described with reference to the appended drawings.

FIG. 1 shows a conventional phase locked loop circuit.

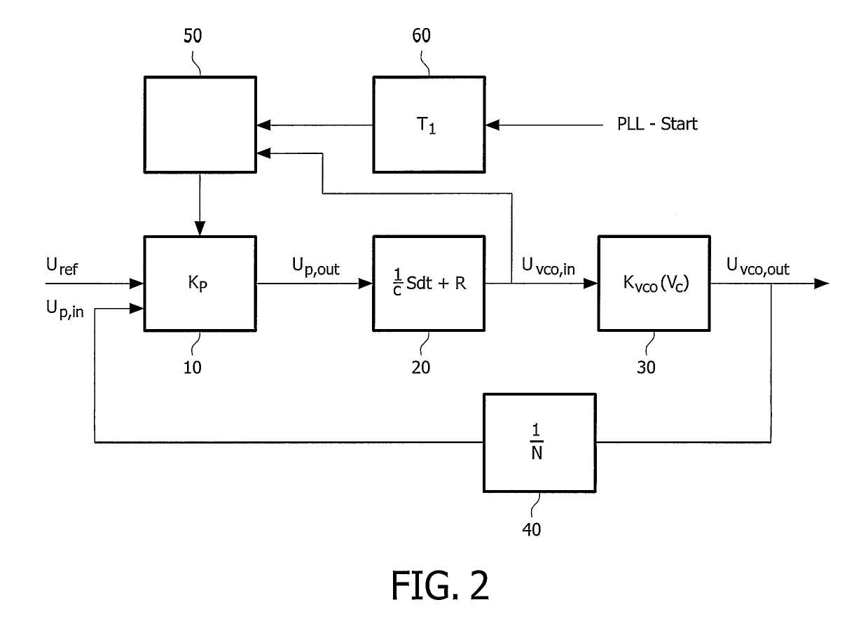

FIG. 2 shows the embodiment of the present invention.

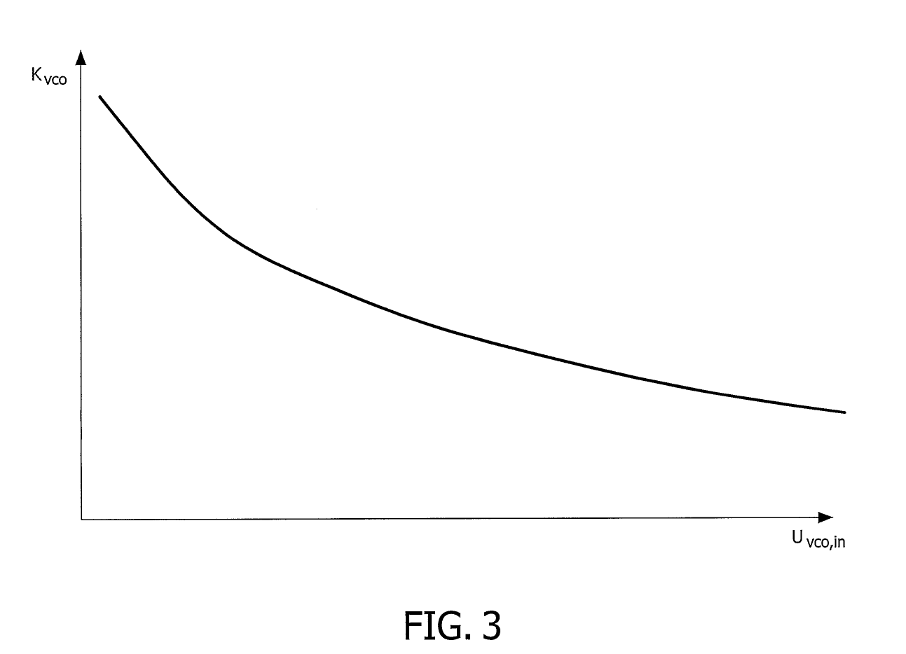

FIG. 3 shows a voltage controlled oscillator gain K_{vco} of the voltage-controlled oscillator 30 of FIG. 2 as a function of the input signal U_{vco,in} of said voltage controlled oscillator 30.

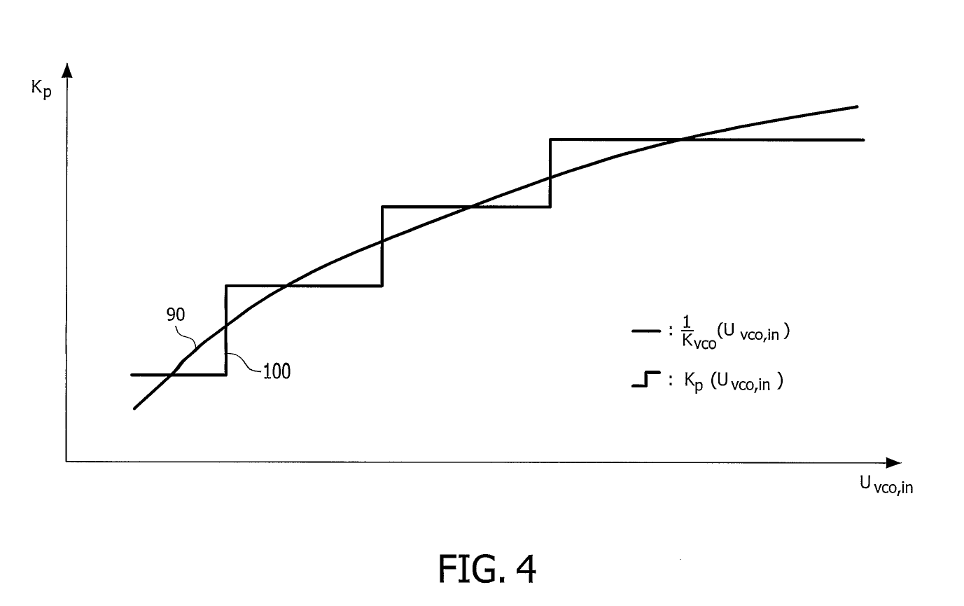

FIG. 4 shows how a controller 50 of the PLL-circuit of FIG. 2 controls a phase comparator gain Kₚ of a phase comparator 10 of FIG. 2 depending on the input voltage U_{vco,in} to the voltage-controlled oscillator 30 of FIG. 2.

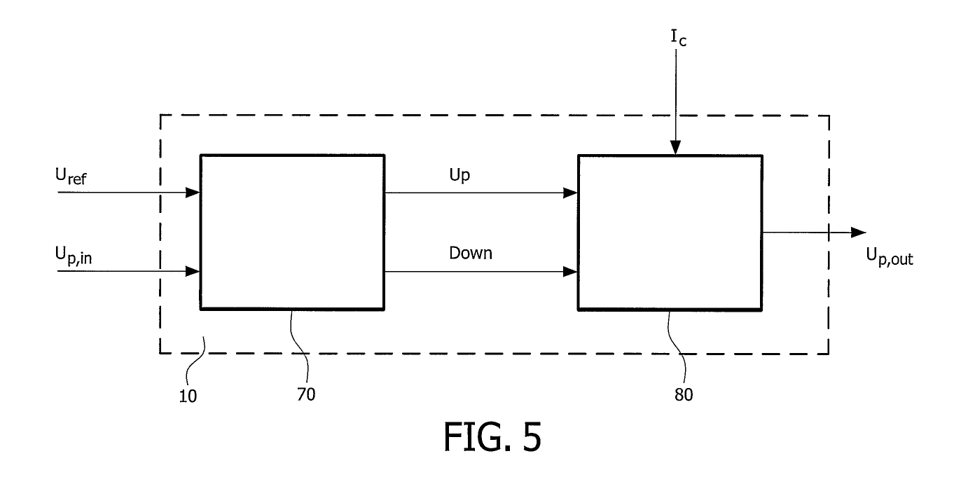

FIG. 5 shows a detailed block diagram of the phase comparator 10 of FIG. 2.

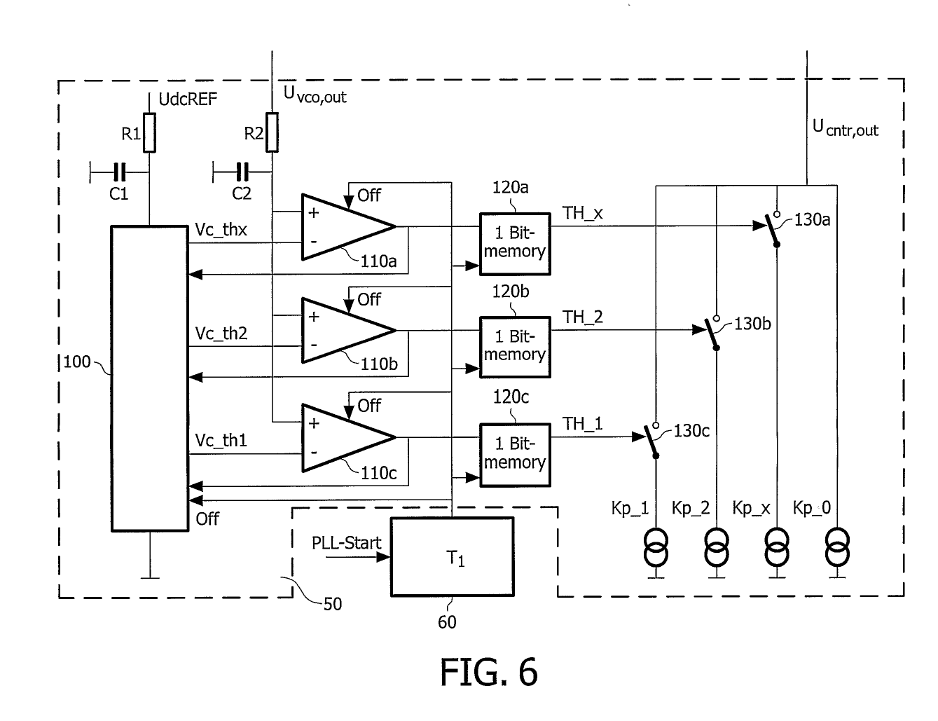

FIG. 6 is a detailed depiction of the controller 50 and timer 60 shown in FIG. 2.

The preferred embodiment of the present invention is depicted in FIG. 2. The phase locked loop circuit of FIG. 2 according to the embodiment of the present invention comprises a phase comparator 10, a loop filter 20, a voltage controlled oscillator 30 as well as a frequency divider 40. U_{ref} stands for the reference signal fed to the PLL and U_{vc,out} corresponds to the output signal Uₒᵤₜ of the PLL. The frequency of the output signal Uₒᵤₜ is equal to the frequency of the reference signal U_{ref} and both signals have a constant phase difference, if the phase locked loop circuit of FIG. 2 is in lock and the frequency divider 40 divides the frequency of the output signal N=1. In general the frequency of the output signal relates to the frequency of the reference signal according to equation 1, if the phase locked loop is in lock. The output signal of the voltage-controlled oscillator 30 is fed back to the input of the phase comparator 10 via the frequency divider 40. The frequency divider 40 is adapted to divide the frequency of the output signal by the factor N. The output signal U_{p,out} of the phase comparator 10 is approximately equal to the phase difference between the input signals to the phase comparator multiplied by Kₚ. Kₚ is the gain of the phase comparator 10. The output signal U_{p,out} in FIG. 2 is fed into the loop filter 20. The loop filter 20 constitutes a passive filter, which integrates the input signal. The loop filter consists of a resistor R and a capacitor C connected to each other in line. The output of the loop filter 20 corresponds to the voltage drop across the capacitor 20. The transfer function F(s) of the loop filter 20 is equal to (R+1/s C) * Fᵣ(s). R is the resistance of the loop filter. C is the capacitance of the integrator. s is equal to i * w, wherein i² =−1 and w is the frequency of the signal at the input of the loop filter. Fᵣ(s) is a ripple filter. The output of the loop filter 20 is the input to the voltage controlled oscillator 30 and constitutes a voltage. Therefore, the loop filter 20 is both used for transforming the output current of the phase comparator into a voltage and suppressing high frequency components of the input signals at the loop filter.

The output of the loop filter 20 constitutes the input to the voltage-controlled oscillator U_{vco,in}. The output of the voltage controlled oscillator U_{vco,out} has a frequency, which is controlled by the input at the VCO. The angular frequency of the output signal is given by equation (7). K_{vco} constitutes the voltage controlled oscillator gain of the voltage-controlled oscillator 30. As long as the input voltages have small amplitudes, the voltage controlled oscillator gain K_{vco} is practically constant. Large amplitudes at the input of the voltage controlled oscillator 30 however change the VCO gain K_{vco} (see equation (8)).

FIG. 3 shows the voltage controlled oscillator gain versus the input voltage U_{vco,in} to the voltage-controlled oscillator. The voltage controlled oscillator gain K_{vco} continuously decreases with increasing input voltages. The controller 50 is provided in FIG. 2, in order to compensate for the input voltage dependency of the voltage controlled oscillator gain K_{vco} shown in FIG. 3. The input voltage to the voltage controlled oscillator U_{vco,in} is also fed to the controller 50. Controller 50 controls the phase comparator gain Kₚ of the phase comparator 10 depending on the voltage U_{vco,in}.

FIG. 4 shows characteristics of the controller 50. Reference sign 90 denotes the size of the function 1/K_{vco} versus the input voltage U_{vco,in} at the voltage controlled oscillator 30 in FIG. 2. Reference sign 100 indicates a step function, that approximates the curve of 1/ K_{vco}. The controller 50 in FIG. 2 is adapted to control the phase comparator gain Kₚ of the phase comparator 10 in FIG. 2 according to the step function shown in FIG. 4.

FIG. 5 is a detailed depiction of the phase comparator 10 shown in FIG. 2. The phase comparator 10 comprises a phase/frequency detector PFD 70 as well as a charge pump 80. The phase/frequency detector 70 has two inputs for receiving the reference signal U_{ref} as well as the input signal U_{p,in} of the phase comparator 10. The PFD 70 has two outputs named up and down. Preferably, the difference between the up and down signal averaged over time corresponds to the phase difference between the input signals to the phase/frequency detector 70 in FIG. 5. The average value of the phase frequency detector output is obtained by depositing charge onto a capacitor during each phase frequency comparison. The charge pump comprises at least one current source, which charges the capacitor in case the up signal is greater than the down signal and discharges the capacitor in case the down signal is greater than the up signal.

FIG. 6 shows a detailed view of the controller 50 as well as the timer 60. The input to the controller 50 is denoted by U_{vco,out} since it corresponds to the input to the voltage-controlled oscillator. The output of the controller 50 is denoted by U_{cntr,out}. The output U_{cntr,out} is connected to four current sources Kₚ_{_{—}}₀, Kₚ_{_{—}}₁, Kₚ_{_{—}}₂, Kₚ_{_{—}}ₓ. Three switches 130a, 130b and 130c are provided between the respective current sources Kₚ_{_{—}}ₓ, Kₚ_{_{—}}₂, Kₚ_{_{—}}₁ and the output line of the controller 50. The current flowing through the output of the controller may be increased by closing the previously mentioned switches. If all switches are closed, the total current at U_{cntr,out} is equal to the sum of the currents of the four current sources Kₚ_{_{—}}₀, Kₚ_{_{—}}₁, Kₚ_{_{—}}₂ and Kₚ_{_{—}}ₓ. The current flowing through the output of the controller 50 is termed I_{c}. This current I_{c} is used for controlling the charge pump 8 shown in FIG. 5. Preferably, the current I_{c} is used to drive the charge pump, i.e. the current I_{c} charges the capacitor within the charge pump 80 in order to integrate the output of the phase frequency detectors 70. Tho gain of the phase comparator Kₚ increases appropriately, if one of the switches 130a, 130b or 130c is closed.

Each of the switches 130a, 130b and 130c is connected via a one bit memory with a respective operational amplifier 110a, 110b and 110c. As long as the controller 50 is operating, the output of the operational amplifiers 110a, 110b and 110c is uninhibited by the one bit memories. If the output at one of said operational amplifiers is high, the respective switch is closed. Each of the operational amplifiers has a plus and a minus input. Each plus input of said operational amplifier is connected via a resistor r2 and a capacitor c2 to the input voltage over the voltage-controlled oscillator U_{vco,in}. The resistor r2 and the capacitor c2 constitute a low pass filter. The voltage at the plus inputs of the operational amplifiers 110a, 110b and 110c is equal to the input voltage at the voltage-controlled oscillator. Each of the minus inputs of the operational amplifiers 110a, 110b and 110c is provided with a constant supply voltage V_{c}_{_{—}}ₜₕ₁,V_{c}_{_{—}}ₜₕ₂ and V_{c}_{_{—}}ₜₕₓ. The control voltages V_{c}_{_{—}}ₜₕ₁,V_{c}_{_{—}}ₜₕ₂ and V_{c}_{_{—}}ₜₕₓ differ such that V_{c}_{_{—}}ₜₕₓ>V_{c}_{_{—}}ₜₕ₂>V_{c}_{_{—}}ₜₕ₁ is valid. Once the input voltage to the plus inputs of the operational amplifiers exceeds one of the control voltages, the respective switch 130a, 130b or 130c is closed and the respective current Kₚ_{_{—}}₁, Kₚ_{_{—}}₂ or Kₚ_{_{—}}ₓ is added to the output of the controller U_{cntr,out}.

Reference sign 100 denotes a voltage divider, which is connected to ground. A reference voltage U_{dcREF} is applied to the voltage divider 100 via a low pass filter consisting of a resistor r1 and a capacitor c1. The voltage divider divides the reference voltage U_{dc} in such a way, that the input voltages V_{c}_{_{—}}ₜₕ₁, V_{c}_{_{—}}ₜₕ₂ and V_{c}_{_{—}}ₜₕₓ to the minus inputs of the operational amplifiers 110a, 110b and 110c is fixed. Optionally the voltage divider comprises a threshold switch for a Schmitt-trigger (threshold detector). In this case the operational amplifiers in FIG. 6 are replaced by threshold detectors. The control voltages to the threshold detectors are changed according to the hysteresis of the detectors.

The timer 60 in FIG. 6 is connected to each of the operational amplifiers 110a, 110b, 110c and the one bit-memories 120a, 120b and 120c. If the time T1 has elapsed after starting the phase locked loop circuit, the control signal from the timer 60 to the controller 50 is changed. The memories 120a, 120b and 120c retain thereafter the respective value from the operational amplifiers. This means that the one bit-memory 120a is high, if the output of the phase comparator 120a is high, once T1 has elapsed. The outputs of the bit-memories thx, th1 and th2 to the switches 130a, 130b and 130c correspond to the value in the respective one bit-memories. Therefore, the amplitude of the output control signal U_{cntr,out} does not change, once the time T1 has elapsed.

1. Phase locked loop circuit comprising:
a phase comparator for detecting a phase difference between an input reference signal and an input signal, wherein is a phase detector gain of said phase comparator,
a voltage controlled oscillator for generating a periodic output signal having an angular frequency depending on an input signal, wherein is a voltage controlled oscillator gain of said voltage controlled oscillator, and
a controller adapted to control the phase detector gain during an operation of the phase locked loop circuit in such a way that a loop gain remains within a predetermined range during the operation of the phase locked loop circuit.

2. Phase locked loop circuit according to claim 1, wherein said controller is adapted to control the phase detector gain in such a way that the phase detector gain is proportional to.

3. Phase locked loop circuit according to claim 1, wherein said controller is adapted to control the phase detector gain in such a way that the phase detector gain is proportional to a step function approximating.

4. Phase locked loop circuit according to claim 1, wherein the controller is adapted to control the phase detector gain depending on the input signal of the voltage controlled oscillator.

5. Phase locked loop circuit according to claim 1, wherein the controller is adapted to stop controlling when a predetermined period of time T1 has elapsed.

6. Method for controlling a phase locked loop circuit comprising:
a phase comparator for detecting a phase difference between an input reference signal and an input signal, wherein is a phase detector gain of said phase comparator and a voltage controlled oscillator for generating a periodic output signal having an angular frequency depending on an input signal, wherein is a voltage controlled oscillator gain of said voltage controlled oscillator, said method comprising the step of:
controlling the phase detector gain during an operation of the phase locked loop circuit in such a way that a loop gain remains within a predetermined range during the operation of the phase locked loop circuit.
